(19) United States
(12) Patent Application Publication
(10) Pub. No.: US 2015/0060912 A1
(43) Pub. Date: Mar. 5, 2015

(54) LIGHT EMITTING DIODE PACKAGE HAVING ZENER DIODE COVERED BY REFLECTIVE MATERIAL

(71) Applicant: ADVANCED OPTOELECTRONIC TECHNOLOGY, INC., Hsinchu Hsien (TW)

(72) Inventors: HOU-TE LIN, Hukou (TW); FU-HSIANG YEH, Hukou (TW); CHAO-HSIUNG CHANG, Hukou (TW); PIN-CHUAN CHEN, Hukou (TW); LUNG-HSIN CHEN, Hukou (TW)

(73) Assignee: ADVANCED OPTOELECTRONIC TECHNOLOGY, INC., Hsinchu Hsien (TW)

(21) Appl. No.: 14/221,296

(22) Filed: Mar. 21, 2014

(30) Foreign Application Priority Data
Aug. 29, 2013 (CN) 2013103833510

(51) Int. Cl. H01L 33/60; H01L 29/866; H01L 29/66; H01L 33/00

(52) U.S. Cl. CPC H01L 33/60; H01L 33/005; H01L 29/866; H01L 29/66106
USPC 257/98; 438/23

(57) ABSTRACT

An exemplary light emitting diode package includes a substrate comprising a first electrode, a second electrode and an insulation layer electrically insulating the first electrode from the second electrode; a light emitting diode is located on the substrate, and electrically connects with the first and second electrodes; a zener diode is located on the substrate, and electrically connects with the first and second electrodes; and a reflecting layer is formed on the zener diode to reflect light emitted from the light emitting diode and toward the zener diode. The disclosure also relates to a method for manufacturing the light emitting diode package.

### BACKGROUND

1. Technical Field

This disclosure generally relates to light sources, and particularly to a light emitting diode (LED) package which has a zener diode covered by reflective material.

2. Description of Related Art

A typical light emitting diode package includes a substrate, a first electrode formed on the substrate, a second electrode formed on the substrate, a light emitting diode located on the substrate and electrically connecting with the first electrode and the second electrode respectively, and a zener diode located on a plane the same as the light emitting diode to protect the light emitting diode from damage caused by current surge or electrostatic discharge. However, a portion of light emitted from the light emitting diode is absorbed by the zener diode, which decreases the lighting efficiency and the brightness of the light emitting diode package.

What is needed, therefore, is a light emitting diode package and a method for manufacturing the light emitting diode package which can overcome the forgoing drawbacks.

### BRIEF DESCRIPTION OF THE DRAWINGS

FIG. 1 is a top plan view of a light emitting diode package in accordance with an embodiment of the present disclosure.

FIG. 2 is a side view of the light emitting diode package of FIG. 1.

FIGS. 3-8 show steps of manufacturing the light emitting diode package of FIG. 1.

### DETAILED DESCRIPTION

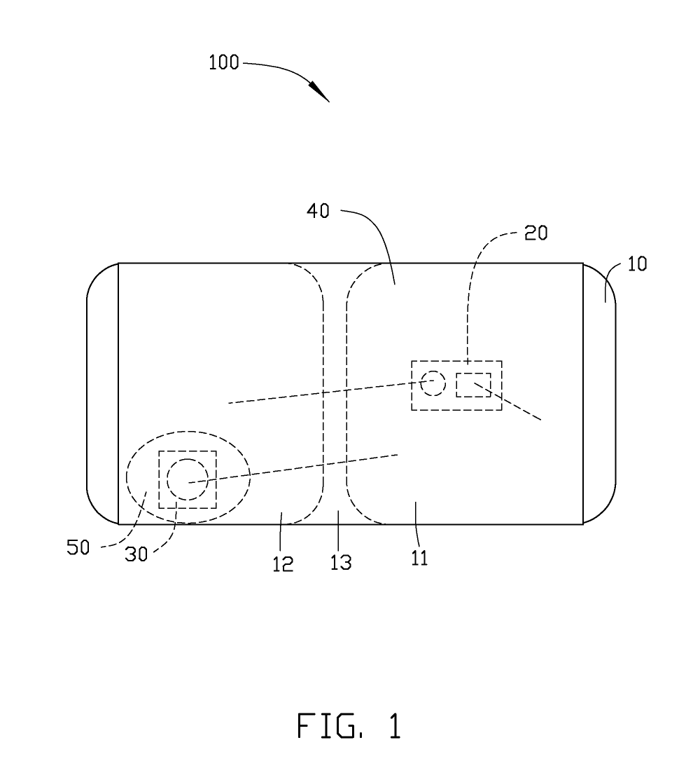

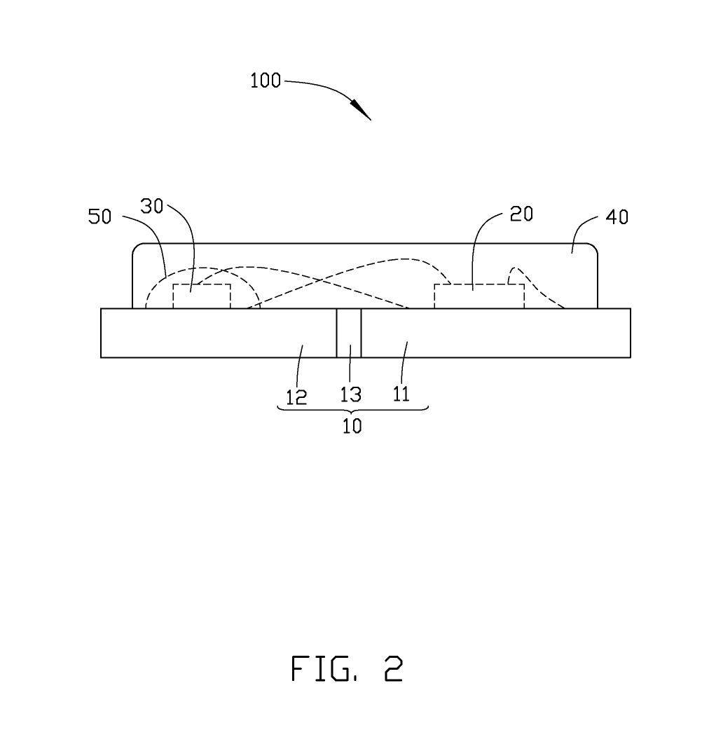

Referring to FIGS. 1-2, an exemplary light emitting diode package 100 of the present disclosure is provided.

The light emitting diode package 100 includes a substrate 10, a light emitting diode 20 located on the substrate 10, a zener diode 30 located on the substrate 10, and an encapsulation layer 40 covering the light emitting diode 20 and the zener diode 30. The light emitting diode 20 is spaced from the zener diode 30. The light emitting diode 20 and the zener diode 30 are mounted on a top surface of the substrate 10, and spaced from each other by a distance.

The substrate 10 has a rectangular configuration. The substrate 10 includes a first electrode 11, a second electrode 12, and an insulation layer 13 sandwiched by the first electrode 11 and the second electrode 12. The first electrode 11 is spaced from the second electrode 12. The insulation layer 13 fills into a gap between the first and second electrodes 11, 12, and contacts with the first electrode 11 and the second electrode 12 respectively. The insulation layer 13 electrically insulates the first electrode 11 from the second electrode 12. In this embodiment, the first electrode is a P-type electrode, and the second electrode 12 is an N-type electrode.

The light emitting diode 20 is formed on the first electrode 11, and electrically connects with the first and second electrodes 11, 12 respectively via conducting wires. The zener diode 30 is formed on the second electrode 12 and electrically connects with the first by a conductive wire and the second electrode 12 by a direct bonding. In this embodiment, the light emitting diode 20 and the zener diode 30 are located at a same side of the substrate 10.

A reflecting layer 50 is formed on the zener diode 30. Preferably, the reflecting layer 50 covers the entire zener diode 30 therein. The reflecting layer 50 reflects light striking the reflecting layer 50. The reflecting layer 50 is formed on the zener diode 30 by means of a glue dispensing process. The reflecting layer 50 is made of opaque materials. In this embodiment, the reflecting layer 50 contains reflective particles, such as TiO₂ or SiO₂ particles in silicone glue.

The encapsulation layer 40 is formed on the substrate 10, and covers the light emitting diode 10, the zener diode 30 and the reflecting layer 50 therein. The encapsulation layer 40 is transparent. The encapsulation layer 40 is made of transparent materials, such as silicone or epoxy resin. Preferably, the encapsulation layer 40 contains fluorescent powders therein, such as garnet fluorescent powders, silicate fluorescent powders, nitride fluorescent powders, nitride oxide fluorescent powders, phosphide fluorescent powders, sulfide fluorescent powders, or a combination thereof. The fluorescent powders can help the LED package 100 to emit light with the required color, for example, white.

According to the exemplary light emitting diode package 100 of the present disclosure, because a reflecting layer 50 is formed on the zener diode 30, light emitted from the light emitting diode 20 and striking the reflecting layer 50 is reflected by the reflecting layer 50 to radiate out of the light emitting diode package 100, rather than is absorbed by the zener diode 30, whereby lighting efficiency and light brightness of the light emitting diode package 100 is increased.

The present disclosure also relates to a method for manufacturing the light emitting diode package 100, and the method includes following steps:

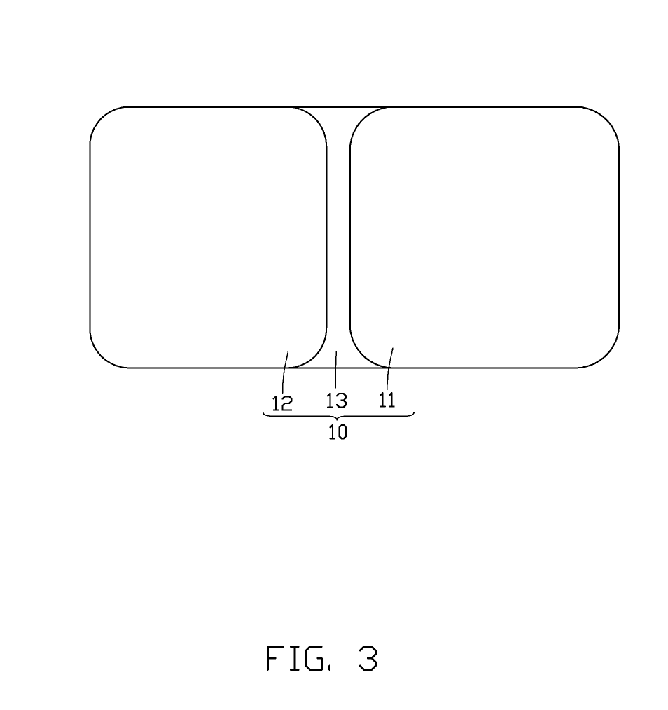

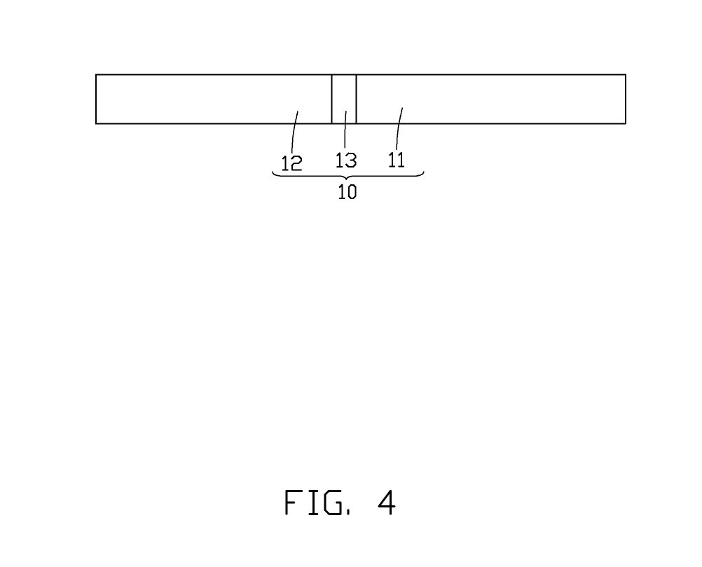

S1: referring to FIGS. 3-4, a substrate 10 is provided. The substrate 10 includes the first electrode 11, the second electrode 12 and the insulation layer 13 electrically insulating the first electrode 11 from the second electrode 12.

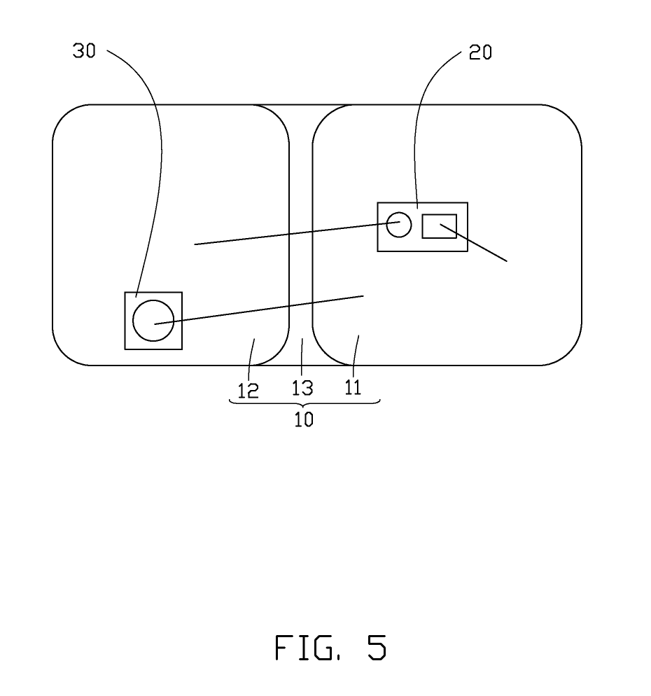

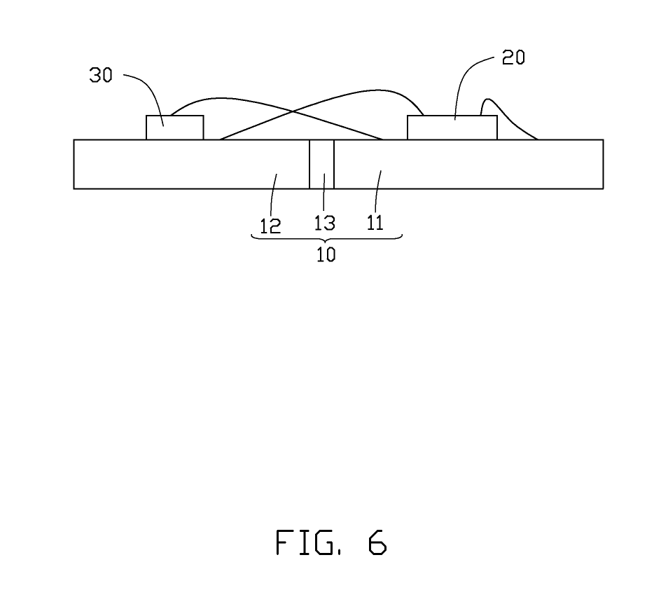

S2: referring to FIGS. 5-6, the light emitting diode 20 is mounted on the first electrode 11 of the substrate 10, and electrically connected to the first and second electrodes 11, 12.

S3: the zener diode 30 is mounted on the second electrode 12, and electrically connected to the first and second electrodes 11, 12.

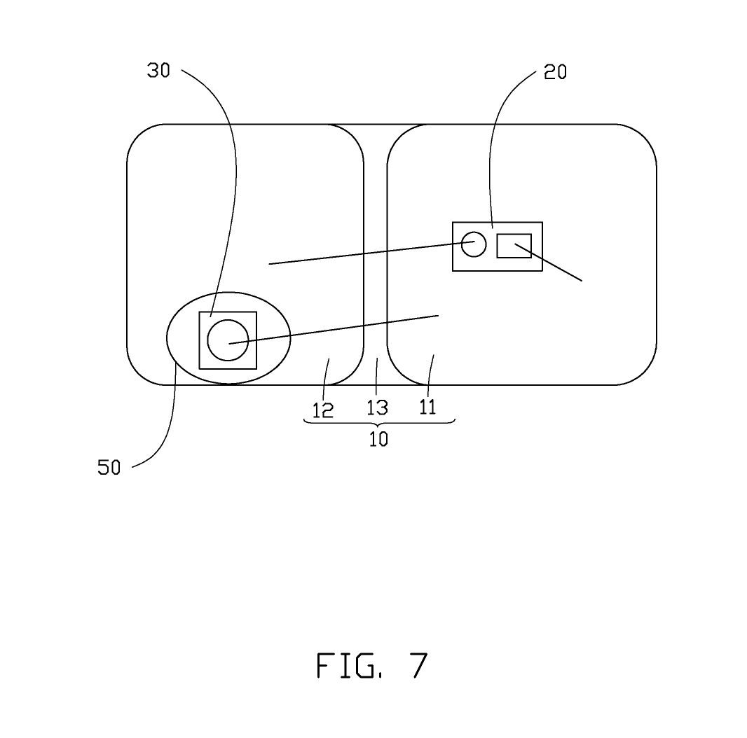

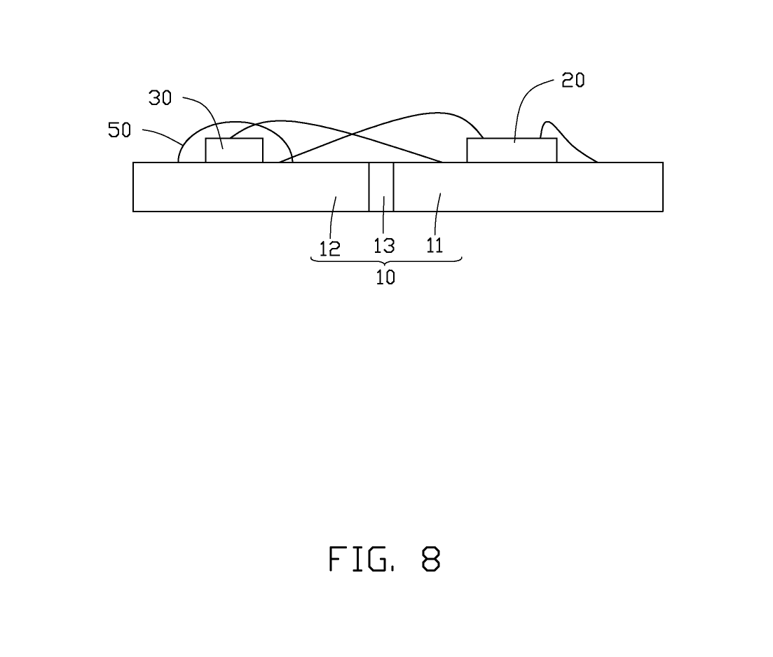

S4: referring to FIGS. 7-8, the reflecting layer 50 is formed on the zener diode 30. In this embodiment, the reflecting layer 50 is formed by means of a glue dispensing process, and the reflecting layer 50 covers the entire zener diode 30 therein.

S5: referring to FIGS. 1-2, the encapsulation layer 40 is formed on the substrate 10 to cover the light emitting diode 20, the zener diode 30 and the reflecting layer 50 therein to form the light emitting diode package 100.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode package, comprising:
a substrate comprising a first electrode, a second electrode and an insulation layer insulating the first electrode with the second electrode;
a light emitting diode located on the substrate, and electrically connecting with the first and second electrodes;
a zener diode located on the substrate, and electrically connecting with the first and second electrodes, the zener diode and the light emitting diode being located on a same side of the substrate; and
a reflecting layer formed on and covering the zener diode to reflect light emitted from the light emitting diode and toward the zener diode.

2. The light emitting diode package of claim 1, wherein the reflecting layer covers an entirety of the zener diode therein.

3. The light emitting diode package of claim 2, wherein the reflecting layer contains reflective particles in silicone glue.

4. The light emitting diode package of claim 3, wherein the reflective particles are TiO₂ or SiO₂ particles.

5. The light emitting diode package of claim 1, wherein the reflecting layer contains reflective particles.

6. The light emitting diode package of claim 5, wherein the reflective particles are TiO₂ or SiO₂ particles.

7. The light emitting diode package of claim 1, wherein the light emitting diode is located on the first electrode and the zener diode is located on the second electrode.

8. The light emitting diode package of claim 1, further comprising an encapsulation layer formed on the substrate, the encapsulation layer covering the light emitting diode, the zener diode and the reflecting layer therein.

9. A method for manufacturing a light emitting diode package, comprising:
S1: providing a substrate, the substrate comprising a first electrode, a second electrode and an insulation layer electrically insulating the first electrode from the second electrode;
S2: arranging a light emitting diode on the first electrode of the substrate, and electrically connecting the light emitting diode with the first and second electrodes;
S3: arranging a zener diode on the second electrode, and electrically connecting the zener diode with the first and second electrodes;
S4: forming a reflecting layer on the zener diode, the reflecting layer reflecting light emitted from the light emitting diode and toward the zener diode.

10. The method of claim 9, wherein the reflecting layer covers the zener diode therein.

11. The method of claim 9, further comprising a step S5 of forming an encapsulation layer on the substrate to cover the light emitting diode, the zener diode and the reflecting layer therein.

12. The method of claim 9, wherein the reflecting layer is formed by means of a glue dispensing process.
